(19) United States
(12) Patent Application Publication
(10) Pub. No.: US 2025/0044351 A1
(43) Pub. Date: Feb. 6, 2025

(54) SEMICONDUCTOR TEST CARRIER, SEMICONDUCTOR TEST APPARATUS INCLUDING THE SAME, AND SEMICONDUCTOR TEST METHOD USING SEMICONDUCTOR TEST APPARATUS

(71) Applicant: SAMSUNG ELECTRONICS CO., LTD., Suwon-si (KR)

(72) Inventor: Heejin Baek, Suwon-si (KR)

(73) Assignee: SAMSUNG ELECTRONICS CO., LTD., Suwon-si (KR)

(21) Appl. No.: 18/632,894

(22) Filed: Apr. 11, 2024

(30) Foreign Application Priority Data
Aug. 4, 2023 (KR) 10-2023-0102435
Nov. 20, 2023 (KR) 10-2023-0160705

(51) Int. Cl. G01R 31/28; G01R 31/311

(52) U.S. Cl. CPC G01R 31/2893; G01R 31/2889; G01R 31/311

(57) ABSTRACT

Provided are a semiconductor test carrier, a semiconductor test apparatuse, and a semiconductor test method. The semiconductor test carrier includes a support plate, a connection member that extends in a horizontal direction from one side of the support plate, and an upper plate on the support plate. The support plate includes a support body having a disk shape and a glass member coupled to the support body. The support body provides a placement hole that vertically penetrates the support body. At least a portion of the glass member is inserted into the placement hole.

### CROSS-REFERENCE TO RELATED APPLICATIONS

This application claims priority to Korean Patent Applications No. 10-2023-0102435 filed on Aug. 4, 2023 and No. 10-2023-0160705 filed on Nov. 20, 2023 in the Korean Intellectual Property Office, the disclosures of which are herein incorporated by reference in their entireties.

### BACKGROUND

The disclosure relate to a semiconductor test carrier, a semiconductor test apparatus including the same, and a semiconductor test method using the semiconductor test apparatus, and more particularly to, a semiconductor test carrier capable of testing a semiconductor chip separated from a wafer, a semiconductor test apparatus including the same, and a semiconductor test method using the semiconductor test apparatus.

Various processes may be performed to fabricate a semiconductor device. For example, the semiconductor device may be fabricated by allowing a substrate to undergo a photolithography process, an etching process, a deposition process, and a test process. The test process may include testing electrical properties of the substrate. In the test process, a probe card may be used to electrically connect a tester to the substrate.

### SUMMARY

Some example embodiments of the disclosure provide a semiconductor test carrier capable of performing hot electron analysis (HEA) on an individual semiconductor chip, a semiconductor test apparatus including the same, and a semiconductor test method using the semiconductor test apparatus.

Some example embodiments of the disclosure provide a semiconductor test carrier capable of using ordinary (or existing) equipment to test an individual semiconductor chip, a semiconductor test apparatus including the same, and a semiconductor test method using the semiconductor test apparatus.

Some example embodiments of the disclosure provide a semiconductor test carrier capable of avoiding (or reducing) discard of good products, a semiconductor test apparatus including the same, and a semiconductor test method using the semiconductor test apparatus.

Some example embodiments of the disclosure provide a semiconductor test carrier capable of testing variously sized semiconductor chips, a semiconductor test apparatus including the same, and a semiconductor test method using the semiconductor test apparatus.

The object of the disclosure is not limited to the mentioned above, and other objects which have not been mentioned above will be clearly understood to those skilled in the art from the following description.

According to some embodiments of the disclosure, a semiconductor test carrier may include: a support plate; a connection member that extends in a horizontal direction from one side of the support plate; and an upper plate on the support plate. The support plate may include: a support body having a disk shape; and a glass member coupled to the support body. The support body may provide a placement hole that vertically penetrates the support body. At least a portion of the glass member may be inserted into the placement hole.

According to some embodiments of the disclosure, a semiconductor test apparatus may include: a lower housing that provides a test space; a window plate in the test space; and a hot electron analysis (HEA) lens downwardly spaced apart from the window plate. The window plate may include: a plate body; and a support device coupled to the plate body. The plate body may provide a plate through hole that vertically penetrates the plate body. At least a portion of the support device may be inserted into the plate through hole. The support device may provide a placement hole that is downwardly recessed from a top surface of the support device.

According to some embodiments of the disclosure, a semiconductor test method may include: placing a single semiconductor chip having a tetragonal shape on a semiconductor test apparatus; applying, by using a probe card of the semiconductor test apparatus, a test power to the single semiconductor chip; and measuring, by using a hot electron analysis (HEA) lens, a characteristic of the single semiconductor chip.

Details of other example embodiments are included in the description and drawings.

### BRIEF DESCRIPTION OF DRAWINGS

The above and/or other aspects will be more apparent by describing certain example embodiments, taken in conjunction with the accompanying drawings.

FIG. 1 illustrates a perspective view showing a semiconductor test apparatus according to some example embodiments of the disclosure.

FIG. 2 illustrates an exploded perspective view showing a semiconductor test apparatus according to some example embodiments of the disclosure.

FIG. 3 illustrates a perspective view showing a semiconductor test carrier according to some example embodiments of the disclosure.

FIG. 4 illustrates a cross-sectional view showing a semiconductor test carrier according to some example embodiments of the disclosure.

FIG. 5 illustrates an exploded cross-sectional view showing a semiconductor test carrier according to some example embodiments of the disclosure.

FIG. 6 illustrates a cross-sectional view showing a semiconductor test carrier according to some example embodiments of the disclosure.

FIG. 7 illustrates a cross-sectional view showing a probe card according to some example embodiments of the disclosure.

FIG. 8 illustrates an enlarged cross-sectional view showing section X of FIG. 7.

FIG. 9 illustrates an enlarged cross-sectional view showing section Y of FIG. 7.

FIG. 10 illustrates a flow chart showing a semiconductor test method according to some example embodiments of the disclosure.

FIGS. 11 to 15 illustrate diagrams showing a semiconductor test method according to the flow chart of FIG. 10.

FIG. 16 illustrates a cross-sectional view showing a window plate according to some example embodiments of the disclosure.

FIG. 17 illustrates an exploded cross-sectional view showing a window plate according to some example embodiments of the disclosure.

FIG. 18 illustrates a plan view showing a window plate according to some example embodiments of the disclosure.

FIG. 19 illustrates a cross-sectional view showing a window plate according to some example embodiments of the disclosure.

FIG. 20 illustrates an exploded cross-sectional view showing a window plate according to some example embodiments of the disclosure.

FIG. 21 illustrates an exploded cross-sectional view showing a window plate according to some example embodiments of the disclosure.

FIG. 22 illustrates a cross-sectional view showing a window plate according to some example embodiments of the disclosure.

FIG. 23 illustrates a plan view showing a window plate according to some example embodiments of the disclosure.

### DETAILED DESCRIPTION

The following will now describe some example embodiments of the disclosure with reference to the accompanying drawings. Like reference numerals may indicate like components throughout the description.

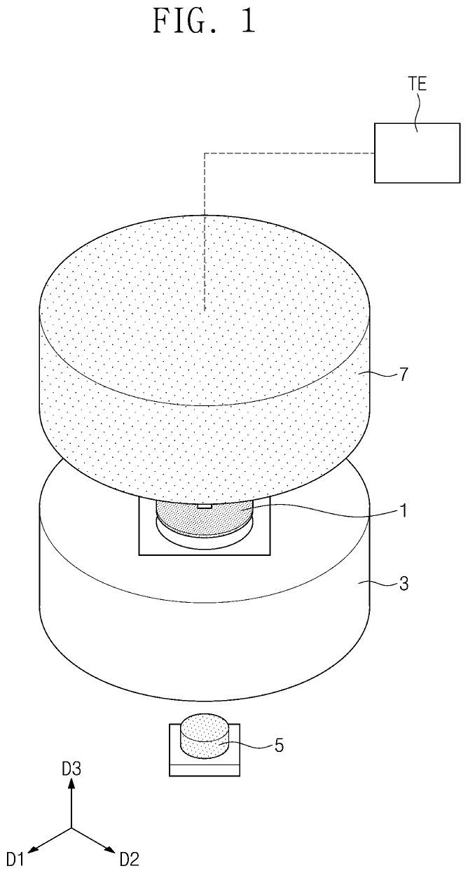

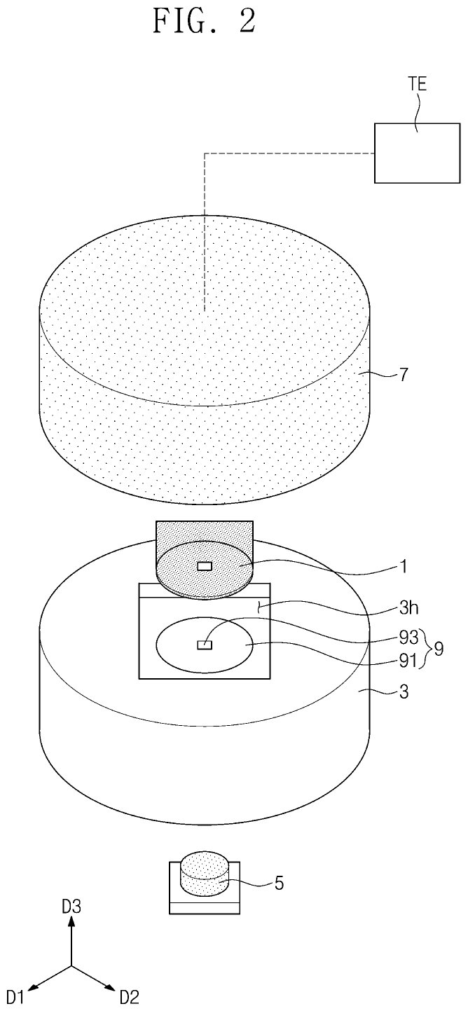

FIG. 1 illustrates a perspective view showing a semiconductor test apparatus according to some example embodiments of the disclosure. FIG. 2 illustrates an exploded perspective view showing a semiconductor test apparatus according to some example embodiments of the disclosure.

In the following description, symbol D1 may indicate a first direction, symbol D2 may indicate a second direction that intersects the first direction D1, symbol D3 may include a third direction that intersects the first direction D1 and the second direction D2. Each of the first direction D1 and the second direction D2 may be called a horizontal direction. The third direction D3 may be called a vertical direction or an upward direction. In the specification, the term “horizontal direction” may be used to refer to the first direction D1 and/or the second direction D2.

Referring to FIGS. 1 and 2, a semiconductor test apparatus according to some example embodiments may be provided. The semiconductor test apparatus may be an apparatus configured to perform various tests on a semiconductor device. For example, the semiconductor test apparatus may perform a hot electron analysis (HEA) test on a semiconductor chip provided in a form of a single chip. The disclosure, however, is not limited thereto, and for example, the semiconductor test apparatus may perform the HEA test on a wafer-type substrate. The semiconductor test apparatus may include a lower housing 3, a semiconductor test carrier 1, a driving mechanism (not shown), a hot electron analysis (HEA) lens 5, a window plate 9, a probe card 7, and a tester TE.

The lower housing 3 may provide a test space 3h. The lower housing 3 may have a cylindrical shape, but the disclosure is not limited thereto. The test space 3h may have, for example, a tetragonal shape. For example, the test space 3h may be tetragonal when viewed in plan.

The semiconductor test carrier 1 may be disposed on the lower housing 3. For example, at least a portion of the semiconductor test carrier 1 may be disposed in the test space 3h. The semiconductor test carrier 1 may support a semiconductor device as a test target. For example, the semiconductor test carrier 1 may support a semiconductor chip provided in a form of a single chip. In a state where a semiconductor chip is disposed on the semiconductor test carrier 1, a HEA test may be performed on the semiconductor chip. The semiconductor test carrier 1 will be further discussed in detail below.

The driving mechanism (not shown) may be connected to the semiconductor test carrier 1. The driving mechanism may drive the semiconductor test carrier 1 to move in the horizontal direction (e.g., direction D1 and/or direction D2). The driving mechanism may include an actuator, such as a motor or a hydraulic device.

The HEA lens 5 may be positioned below the semiconductor test carrier 1. The HEA lens 5 may be disposed downwardly spaced apart from the semiconductor test carrier 1. For example, the HEA lens 5 may be positioned below the lower housing 3. The HEA lens 5 may measure a characteristic of a semiconductor chip disposed on the semiconductor test carrier 1. The HEA lens 5 may measure a characteristic from a bottom surface of the semiconductor chip to analyze the semiconductor chip (e.g., perform hot electrons analysis of the semiconductor chip). The HEA lens 5 may include one or more of a charged coupled device (CCD) chip and a CMOS image sensor (CIS) chip. A detailed description thereof will be further discussed below.

The window plate 9 may be positioned between the semiconductor test carrier 1 and the HEA lens 5. The window plate 9 may be positioned in the lower housing 3. The window plate 9 may be disposed in the test space 3h. The HEA lens 5 may measure a characteristic of a semiconductor chip disposed on the semiconductor test carrier 1 through the window plate 9. The window plate 9 may include a plate body 91 and a window 93. The plate body 91 may provide a lower through hole. The lower through hole may vertically penetrate the plate body 91. The plate body 91 may have a disk shape, but the disclosure is not limited thereto. The window 93 may be coupled to (or combined with) the plate body 91. For example, the window 93 may be inserted into the lower through hole. The window 93 may include glass, but the disclosure is not limited thereto. The window 93 may have a tetragonal shape. For example, the widow 93 may have a rectangular shape when viewed in plan, but the disclosure is not limited thereto. The window plate 9 will be further discussed in detail below.

The probe card 7 may be positioned on the semiconductor test carrier 1. The probe card 7 may be selectively in contact with a semiconductor chip on the semiconductor test carrier 1. The probe card 7 will be further discussed in detail below.

The tester TE may be connected to the probe card 7. The tester TE may supply the probe card 7 with a test power. A detailed description thereof will be further discussed below.

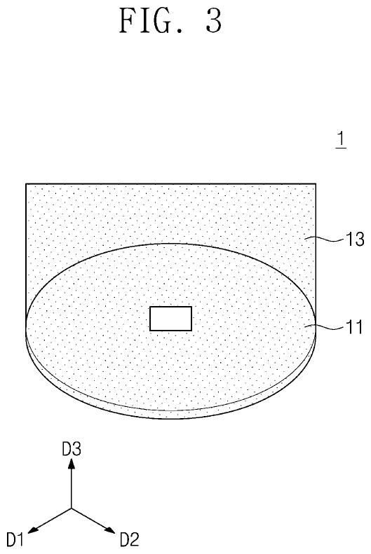

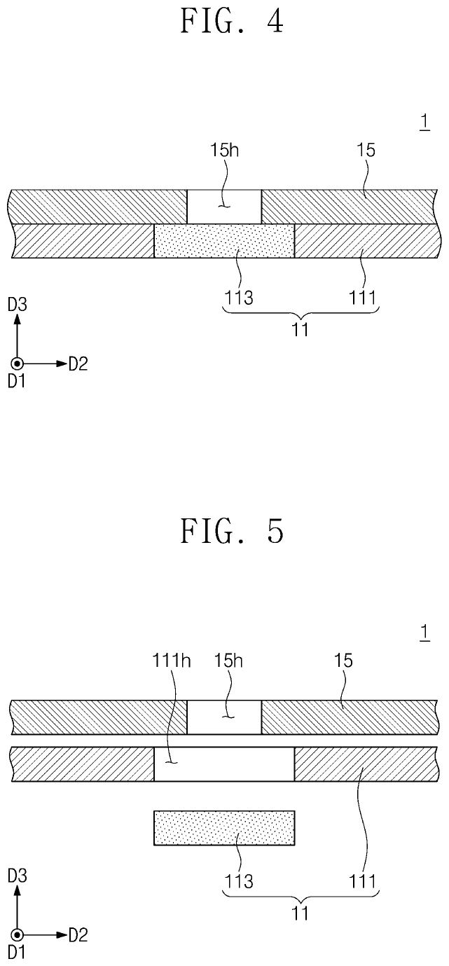

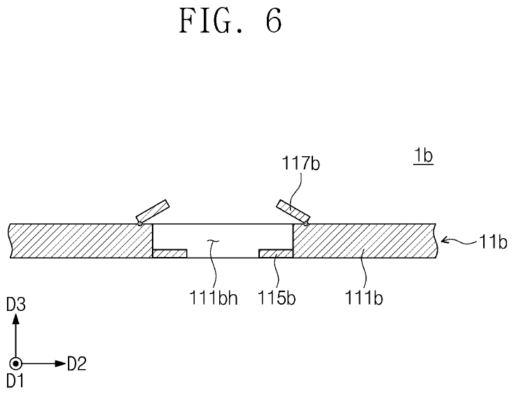

FIG. 3 illustrates a perspective view showing a semiconductor test carrier according to some example embodiments of the disclosure. FIG. 4 illustrates a cross-sectional view showing a semiconductor test carrier according to some example embodiments of the disclosure. FIG. 5 illustrates an exploded cross-sectional view showing a semiconductor test carrier according to some example embodiments of the disclosure.

Referring to FIGS. 3 to 5, the semiconductor test carrier 1 may include a support plate 11, a connection member 13, and an upper plate 15. FIG. 4 illustrates a case in which the connection member 13 is coupled to (or combined with) the support body 111

The support plate 11 may support a semiconductor chip. The support plate 11 may include a support body 111 and a glass member 113.

The support body 111 may provide a placement hole 111h. The placement hole 111h may vertically penetrate the support body 111. The placement hole 111h may have a tetragonal shape. For example, the placement hole 111h may have a rectangular shape when viewed in plan. In some embodiments, the placement hole 111h may have a width of about 1 cm to about 15 cm. The support body 111 may have a disk shape. The disclosure, however, is not limited thereto, and the support body 111 may have any other suitable shapes.

The glass member 113 may be coupled to (or combined with) the support body 111. At least a portion of the glass member 113 may be inserted into the placement hole 111h. The glass member 113 may have a tetragonal shape. The glass member 113 may have a width substantially the same as or similar to that of the placement hole 111h. For example, the glass member 113 may have a width of about 1 cm to about 15 cm. The glass member 113 may include a sapphire glass, but the disclosure is not limited thereto.

The connection member 13 may be connected to the support plate 11. The connection member 13 may extend in the horizontal direction (e.g., in the direction D1 and/or direction D2) from one side of the support plate 11. The connection member 13 may have a plate shape. More specifically, the connection member 13 may have a square plate shape with one side distorted. In the example embodiments illustrated in FIGS. 3-4, the connection member 13 may extend in the horizontal direction D1 and overlap with the support plate 11 in the horizontal direction D1. Thus, the connection member 13 may not be shown in the cross-sectional view of FIG. 4 or FIG. 5. However, this is only an example and the disclosure is not limited thereto. The connection member 13 may support the support plate 11. The connection member 13 may be connected to the driving mechanism. The support plate 11 may be connected through the connection member 13 to the driving mechanism. The driving mechanism may drive the support plate 11 to move in the horizontal direction.

The upper plate 15 may be positioned on the support plate 11. The upper plate 15 may provide an upper placement hole 15h. The upper placement hole 15h may vertically penetrate the upper plate 15. The upper placement hole 15h may be positioned on the placement hole 111h. The upper placement hole 15h may be positioned on the glass member 113 (refer to FIG. 4). The upper placement hole 15h may have a tetragonal shape. For example, the upper placement hole 15h may have a tetragonal shape when viewed in plan. The upper placement hole 15h may have a width less than that of the placement hole 111h. For example, the upper placement hole 15h may have a width of about 0.5 cm to about 5 cm. The upper placement hole 15h may cause at least a portion of a top surface of the glass member 113 to be exposed on a space on the upper plate 15. In a state where a semiconductor chip is inserted into the upper placement hole 15h, the semiconductor chip may be supported by the glass member 113.

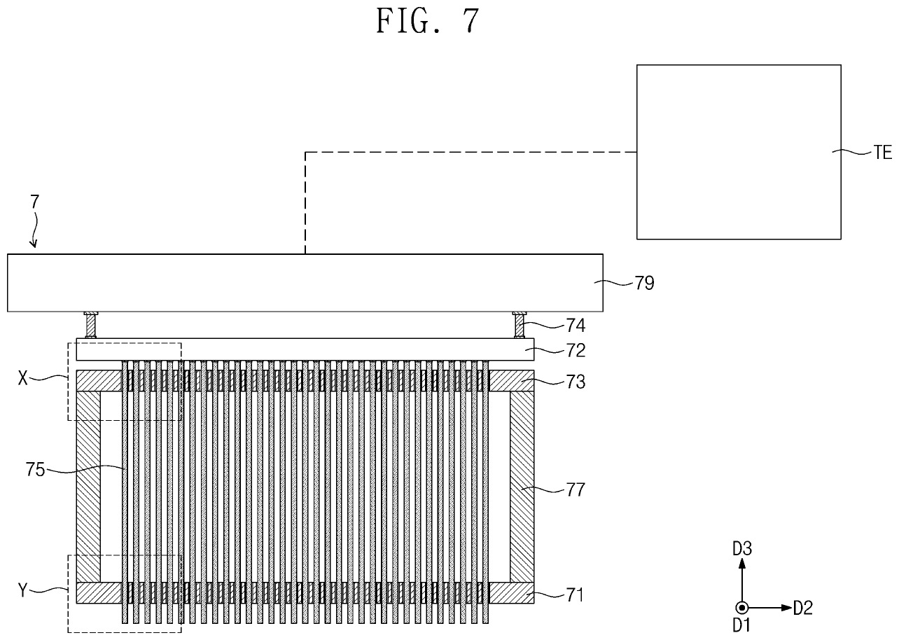

FIG. 6 illustrates a cross-sectional view showing a semiconductor test carrier according to some example embodiments of the disclosure.

In the example embodiment that is described below, omission will be made to avoid a repetitive description of components that are the same as or similar to those discussed with reference to FIGS. 1 to 5.

Referring to FIG. 6, a semiconductor test carrier 1b may include a support plate 11b. The support plate 11b may include a support body 111b, an inner support member 115b, and a clamp member 117b.

The support body 111b may provide a placement hole 111bh. The placement hole 111bh may vertically penetrate the support body 111b.

The inner support member 115b may be positioned in the placement hole 111bh. The inner support member 115b may extend in the horizontal direction (e.g., direction D2) from an inner surface (e.g., an inner side surface extending in the vertical (e.g., D3) direction) of the support body 111b. Therefore, a width of a lower end of the placement hole 111bh may be less than that of an upper end of the placement hole 111bh. For example, a step difference may be provided on inner surfaces of the support body 111b and the inner support member 115 that define the placement hole 111bh.

The clamp member 117b may be coupled to (or combined with) the support body 111b. The clamp member 117b may be positioned on an edge of the placement hole 111bh. The clamp member 117b may be rotatable. Thus, the clamp member 117b may fix a semiconductor chip disposed in the placement hole 111bh.

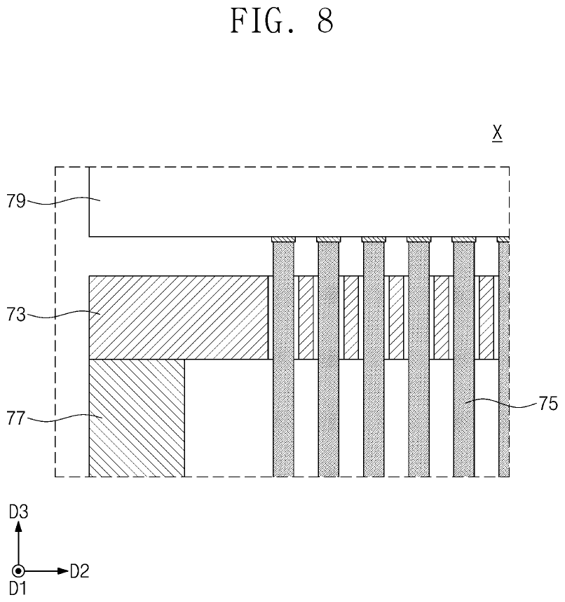

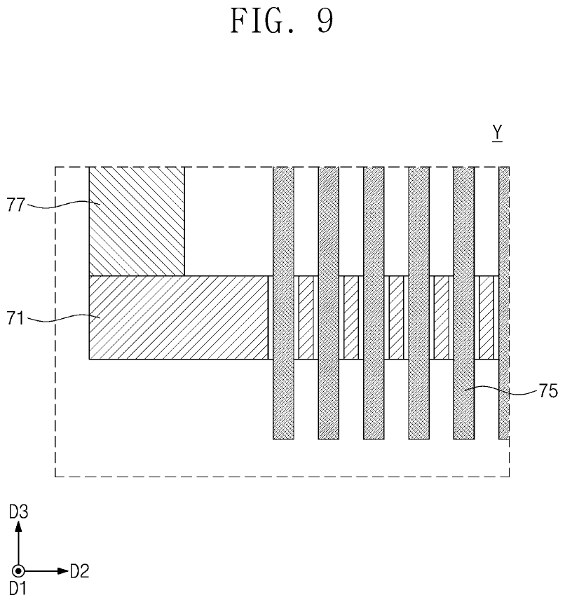

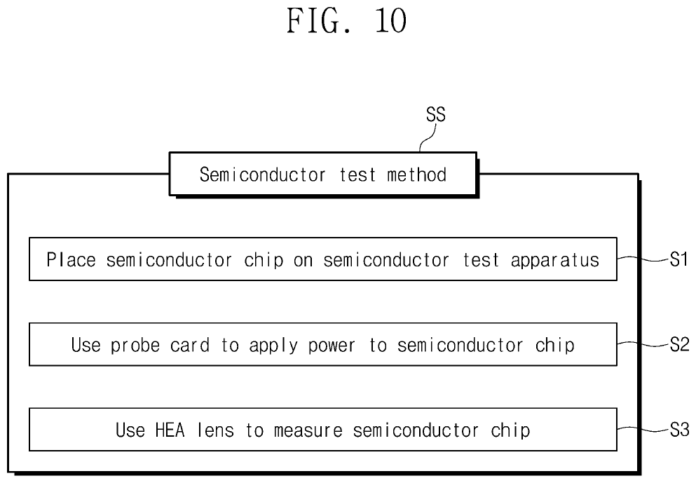

FIG. 7 illustrates a cross-sectional view showing a probe card according to some example embodiments of the disclosure. FIG. 8 illustrates an enlarged cross-sectional view showing section X of FIG. 7. FIG. 9 illustrates an enlarged cross-sectional view showing section Y of FIG. 7.

Referring to FIGS. 7 to 9, the probe card 7 may electrically connect the tester TE to a semiconductor device. The probe card 7 may be in contact with the semiconductor device. The probe card 7 may include a substrate 79, an interposer 74, a space transformer 72, a lower plate 71, an upper plate 73, a plate support member 77, and a needle 75.

The substrate 79 may be electrically connected to the tester TE. The substrate 79 may intermediate an electrical connection between the needle 75 and the tester TE. For example, a test power supplied from the tester TE may be transmitted through the substrate 79 to the needle 75. The substrate 79 may include a printed circuit board (PCB), but the disclosure is not limited thereto.

The interposer 74 may electrically connect the substrate 79 and the space transformer 72 to each other. The interposer 74 may be provided in plural. The plurality of interposers 74 may be disposed spaced apart from each other in the horizontal direction between the substrate 79 and the space transformer 72.

The space transformer 72 may connect the substrate 79 and the needle 75 to each other. The space transformer 72 may be positioned below the substrate 79. The space transformer 72 may perform a pitch conversion function between the substrate 79 and the needle 75.

The lower plate 71 may have a plate shape that extends in the horizontal direction. The lower plate 71 may include a dielectric material such as ceramic and/or plastic. The disclosure, however, is not limited thereto, and a portion of the lower plate 71 may include a conductive material. The lower plate 71 may support a portion of the needle 75. The lower plate 71 may provide a lower through hole. A portion of the needle 75 may be inserted into the lower through hole.

The upper plate 73 may be disposed spaced apart from the lower plate 71 in the vertical direction. Therefore, a space may be present between the upper plate 73 and the lower plate 71. The upper plate 73 may have a plate shape that extends in the horizontal direction. The upper plate 73 may include a dielectric material such as ceramic and/or plastic. The disclosure, however, is not limited thereto, and a portion of the upper plate 73 may include a conductive material. The upper plate 73 may support a portion of the needle 75. The upper plate 73 may provide an upper through hole. A portion of the needle 75 may be inserted into the upper through hole. A detailed description thereof will be further discussed below.

The plate support member 77 may connect the lower plate 71 and the upper plate 73 to each other. For example, the plate support member 77 may upwardly extend from the lower member 71 to the upper plate 73. A relative distance between the lower plate 71 and the upper plate 73 may be fixed to be constant by the plate support member 77. The disclosure, however, is not limited thereto, and when the plate support member 77 includes a flexible material, a relative distance between the lower plate 71 and the upper plate 73 may be changed by an external force.

The needle 75 may be electrically connected to the tester TE. For example, the needle 75 may be electrically connected to the tester TE through the substrate 79, the interposer 74, and the space transformer 72. In this case, an upper end of the needle 75 may be coupled to (or combined with) the space transformer 72. The needle 75 may include a conductive material.

The needle 75 may extend vertically. For example, the probe card 7 according to the disclosure may be a vertical probe card. The disclosure, however, is not limited thereto, and the needle 75 may have, for example, a cantilever shape. For example, the probe card 7 according to the disclosure may be a cantilever probe card.

The needle 75 may vertically penetrate the upper plate 73 and the lower plate 71. The needle 75 may be provided in plural. The plurality of needles 75 may be disposed spaced apart from each other in the horizontal direction. Unless otherwise specially stated, a single needle 75 will be discussed by way of an example.

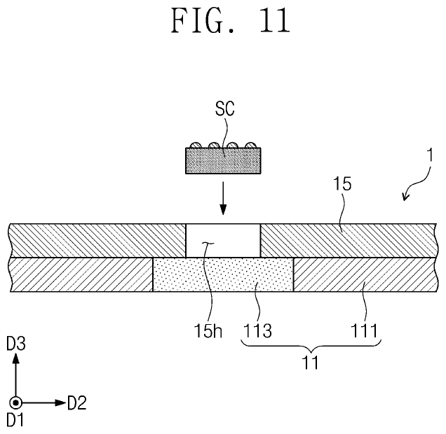

FIG. 10 illustrates a flow chart showing a semiconductor test method according to some example embodiments of the disclosure.

Referring to FIG. 10, a semiconductor test method SS may be provided. The semiconductor test method SS may be a way of testing a semiconductor chip by using the semiconductor test apparatus discussed with reference to FIGS. 1 to 9. The semiconductor test method SS may include placing a semiconductor chip on a semiconductor test apparatus (S1), using a probe card to apply a test power to the semiconductor chip (S2), and using a hot electron analysis (HEA) lens to measure a characteristic of the semiconductor chip (S3).

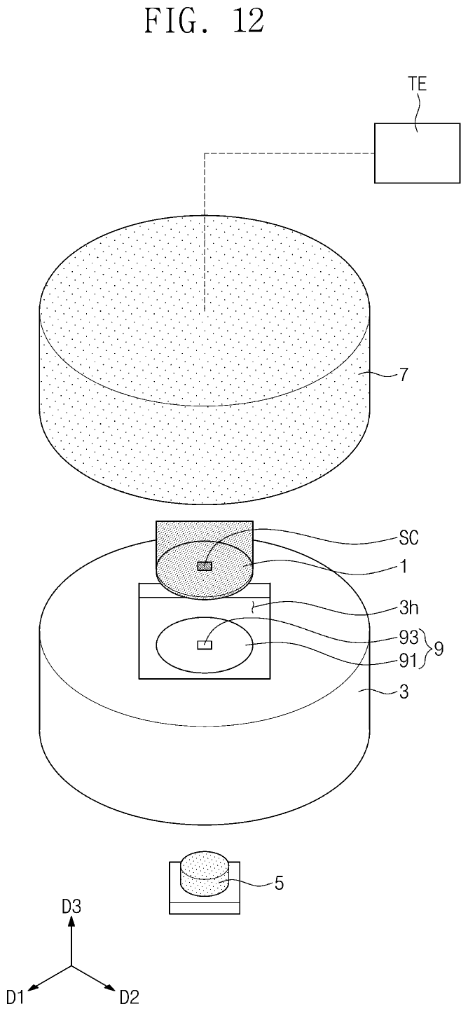

The semiconductor test method SS of FIG. 10 will be described below with reference to FIGS. 11 to 15.

FIGS. 11 to 15 illustrate diagrams showing a semiconductor test method according to the flow chart of FIG. 10.

Referring to FIGS. 10, 11, and 12, the placement step S1 may include placing a semiconductor chip SC on the support body 111. For example, the semiconductor chip SC may be disposed on the support body 111 to allow at least a portion of the semiconductor chip SC to be inserted into the upper placement hole 15h. In some embodiments, the semiconductor chip SC may be disposed on the glass member 113. For example, the semiconductor chip SC may be supported by the glass member 113. The semiconductor chip SC may be provided in the form of a single chip. The semiconductor chip SC may have a tetragonal shape. For example, the semiconductor chip SC may be a tetragonal die. In a state where the semiconductor chip SC is disposed on the semiconductor test carrier 1, the semiconductor test carrier 1 may be disposed on the window plate 9. A bottom surface of the semiconductor chip SC may be exposed to the HEA lens 5 through the glass member 113 and the window 93.

Referring to FIGS. 10, 13, 14, and 15, the test power step S2 may include allowing the needle 75 of the probe card 7 to contact a top surface of the semiconductor chip SC. A test power supplied from the tester TE may be transmitted through the needle 75 to the semiconductor chip SC.

Referring back to FIGS. 10, 12, and 13, the measurement step S3 may include allowing the HEA lens 5 to measure a characteristic from the bottom surface of the semiconductor chip SC through the window plate 9 and the glass member (see 113 of FIG. 11). In a state where the tester TE applies a test power to the semiconductor chip SC, the HEA lens 5 may measure a characteristic from the bottom surface of the semiconductor chip SC to identify conditions of the semiconductor chip SC.

According to a semiconductor test carrier, a semiconductor test apparatus including the same, and a semiconductor test method using the semiconductor test apparatus in accordance with some examples of the disclosure, a hot electron analysis (HEA) test may be performed on a semiconductor chip provided in the form of a single chip. For example, an entire wafer may not be needed (or tested) to test one semiconductor chip. Therefore, the HEA test may be performed in such a way that, among a plurality of semiconductor chips in the wafer, only defective products are removed and good products remain to be used. Accordingly, it may possible to avoid discard of good products.

According to a semiconductor test carrier, a semiconductor test apparatus including the same, and a semiconductor test method using the semiconductor test apparatus in accordance with some examples of the disclosure, an ordinary (or existing) semiconductor test apparatus may be used to perform a hot electron analysis (HEA) test on a single chip. It may thus be possible to save costs.

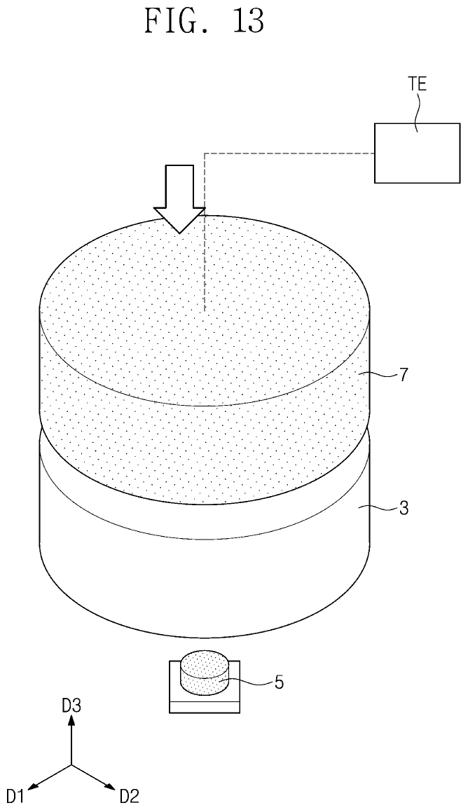

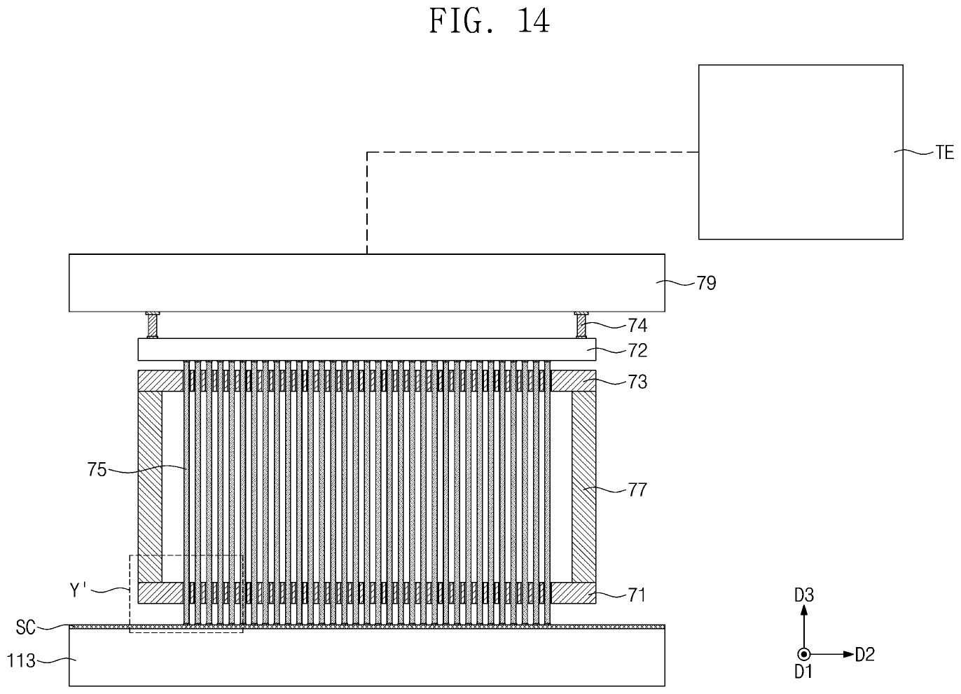

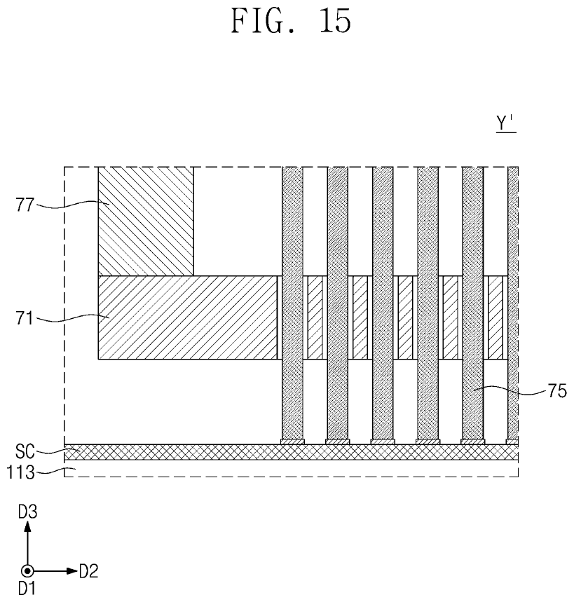

FIG. 16 illustrates a cross-sectional view showing a window plate according to some example embodiments of the disclosure. FIG. 17 illustrates an exploded cross-sectional view showing a window plate according to some example embodiments of the disclosure. FIG. 18 illustrates a plan view showing a window plate according to some example embodiments of the disclosure.

The following description may omit a description of components substantially the same as or similar to those discussed with reference to FIGS. 1 to 15.

Referring to FIGS. 16 to 18, the window plate 9 may support a semiconductor chip. For example, a semiconductor chip provided in the form of a single chip may be disposed on the window plate 9, not on the semiconductor test carrier 1 discussed with reference to FIG. 4. In this case, the semiconductor test carrier 1 may be omitted. The window plate 9 may include a plate body 91, a support device 93, and a lower support member 95. The support device 93 may correspond to the window 93 discussed with reference to FIGS. 1 and 2.

The plate body 91 may provide a plate through hole 91h. The plate through hole 91h may vertically penetrate the plate body 91. The plate body 91 may have a disk shape, but the disclosure is not limited thereto.

The support device 93 may be coupled to (or combined with) the plate body 91. For example, at least a portion of the support device 93 may be inserted into the plate through hole 91h. The support device 93 may have square plate shape. The support device 93 may support a semiconductor chip. For example, differently from that discussed with reference to FIGS. 4 to 15, a semiconductor chip may be disposed not on the semiconductor test carrier (see 1 of FIG. 4), but on the support device 93. A bottom surface of the support device 93 may be exposed toward the HEA lens (see 5 of FIG. 2). The support device 93 may have, for example, a tetragonal shape. The support device 93 may have a width of about 1 cm to about 15 cm. The support device 93 may include a sapphire glass, but the disclosure is not limited thereto. The support device 93 may provide a placement hole 93h. The placement hole 93h may be downwardly recessed from a top surface of the support device 93. In a state where a semiconductor chip is inserted into the placement hole 93h, the semiconductor chip may be supported by the support device 93. The placement hole 93h may have a tetragonal shape. The placement hole 93h may have a width of about 0.5 cm to about 5 cm.

The lower support member 95 may be positioned below the plate through hole 91h. The lower support member 95 may have a plate shape with hole. The lower support member 95 may be coupled to (or combined with) a bottom surface of the plate body 91. The lower support member 95 may support the support device 93. For example, the support device 93 may be supported by a top surface of the lower support member 95.

According to a semiconductor test apparatus and a semiconductor test method using the semiconductor test apparatus in accordance with some embodiments of the disclosure, a window plate may support a semiconductor chip. Therefore, a semiconductor test carrier may be omitted. Accordingly, the semiconductor test apparatus may be simplified.

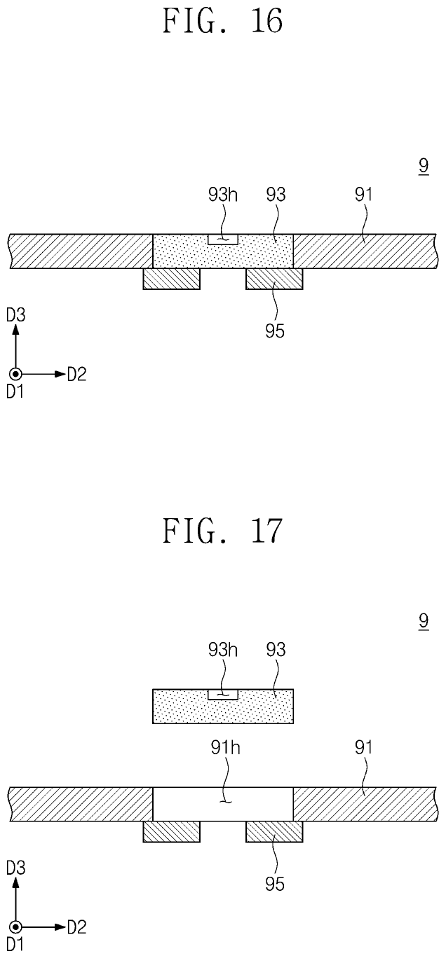

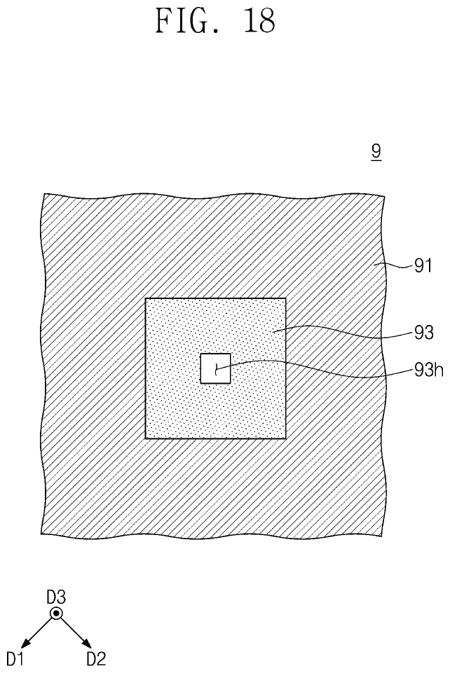

FIG. 19 illustrates a cross-sectional view showing a window plate according to some example embodiments of the disclosure. FIG. 20 illustrates an exploded cross-sectional view showing a window plate according to some example embodiments of the disclosure.

The following description may omit a description substantially the same as or similar to that discussed with reference to FIGS. 1 to 18.

Referring to FIGS. 19 and 20, a window plate 9b may be provided. The window plate 9b may include a plate body 91b, a support device 93b, a lower support member 95b, and an insertion member 97b.

The insertion member 97b may be inserted into a plate through hole 91bh. The insertion member 97b may support the support device 93b. The support device 93b may include a placement hole 93bh. For example, the support device 93b may be disposed on the insertion member 97b. In a state where the support device 93b is disposed on the insertion member 97b, a test may be performed on a semiconductor chip inserted into the placement hole 93bh. As the insertion member 97b is used, it may be possible to use the support device 93b having various sizes.

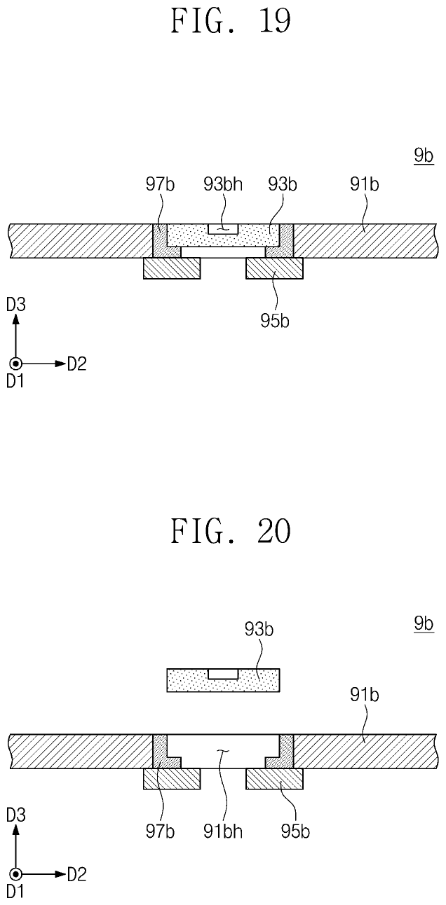

FIG. 21 illustrates an exploded cross-sectional view showing a window plate according to some example embodiments of the disclosure.

The following description may omit a description substantially the same as or similar to that discussed with reference to FIGS. 1 to 20.

Referring to FIG. 21, a window plate 9c may be provided. The window plate 9c may include a plate body 91c, a support device 93c, a lower support member 95c, and an insertion member 97c. However, differently from the example embodiments discussed with reference to FIGS. 19 and 20, the support device 93c may not provide a placement hole. A semiconductor chip may be disposed on the support device 93c. For example, a semiconductor chip may be supported by a top surface of the support device 93c.

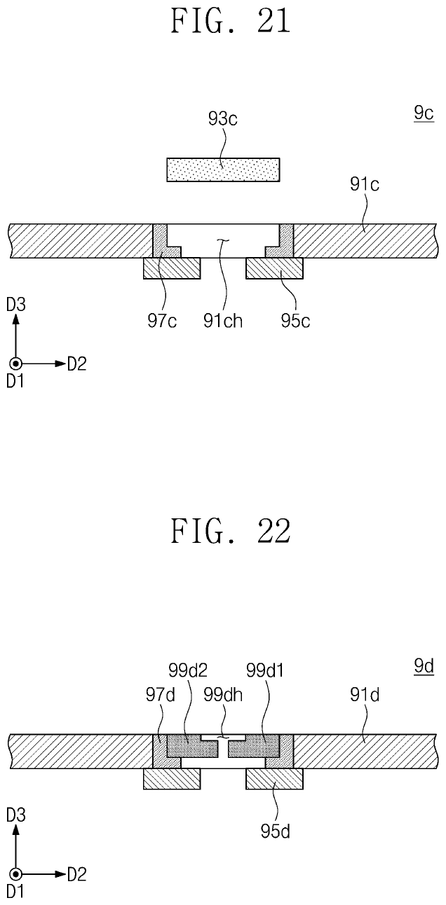

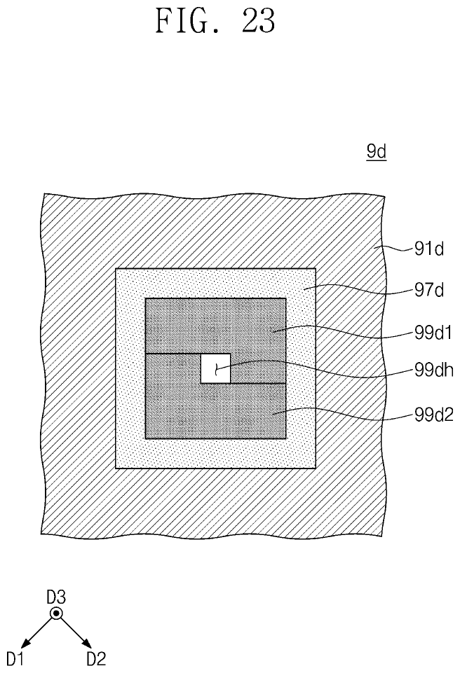

FIG. 22 illustrates a cross-sectional view showing a window plate according to some example embodiments of the disclosure. FIG. 23 illustrates a plan view showing a window plate according to some example embodiments of the disclosure.

The following description may omit a description substantially the same as or similar to that discussed with reference to FIGS. 1 to 21.

Referring to FIGS. 22 and 23, a window plate 9d may be provided. The window plate 9d may include a plate body 91d, a support device (not shown), a lower support member 95d, an insertion member 97d, a first size adjustment member 99d1, and a second size adjustment member 99d2.

The first size adjustment member 99d1 and the second size adjustment member 99d2 may be disposed on the insertion member 97d. The first size adjustment member 99d1 and the second size adjustment member 99d2 may define a size adjustment placement hole 99dh. The support device may be supported on the first size adjustment member 99d1 and the second size adjustment member 99d2. For example, the support device may be disposed in the size adjustment placement hole 99dh. Each of the first size adjustment member 99d1 and the second size adjustment member 99d2 may include a magnetic material. Therefore, a prompt coupling may be performed between the insertion member 97d and each of the first size adjustment member 99d1 and the second size adjustment member 99d2. A size of the size adjustment placement hole 99dh may be adjusted by changing sizes of the first size adjustment member 99d1 and the second size adjustment member 99d2. Accordingly, it may be possible to use the support device having various sizes.

According to a semiconductor test carrier of the disclosure, a semiconductor test apparatus including the same, and a semiconductor test method using the semiconductor test apparatus, hot electron analysis (HEA) may be performed on an individual semiconductor chip.

According to a semiconductor test carrier of the disclosure, a semiconductor test apparatus including the same, and a semiconductor test method using the semiconductor test apparatus, an ordinary (or existing) apparatus may be utilized to test an individual semiconductor chip.

According to a semiconductor test carrier of the disclosure, a semiconductor test apparatus including the same, and a semiconductor test method using the semiconductor test apparatus, good products may be prevented from being discarded.

According to a semiconductor test carrier of the disclosure, a semiconductor test apparatus including the same, and a semiconductor test method using the semiconductor test apparatus, a test may be performed on variously sized semiconductor chips.

Effects of the disclosure are not limited to the mentioned above, other effects which have not been mentioned above will be clearly understood to those skilled in the art from the following description.

Although the disclosure have been described in connection with some example embodiments of the disclosure illustrated in the accompanying drawings, it will be understood to those skilled in the art that various changes and modifications may be made without departing from the technical spirit and essential feature of the disclosure. It therefore will be understood that the embodiments described above are just illustrative but not limitative in all aspects.

What is claimed is:

1. A semiconductor test carrier, comprising:
a support plate;
a connection member that extends in a horizontal direction from one side of the support plate; and
an upper plate on the support plate,
wherein the support plate comprises:
a support body having a disk shape; and
a glass member coupled to the support body,
wherein the support body provides a placement hole that vertically penetrates the support body, and
wherein at least a portion of the glass member is inserted into the placement hole.

2. The semiconductor test carrier of claim 1, wherein the upper plate provides an upper placement hole that vertically penetrates the upper plate, and
wherein the upper placement hole is positioned on the glass member.

3. The semiconductor test carrier of claim 2, wherein a width of the upper placement hole is less than a width of the glass member.

4. The semiconductor test carrier of claim 2, wherein the upper placement hole has a tetragonal shape, and
wherein a width of the upper placement hole is in a range of about 0.5 cm to about 5 cm.

5. The semiconductor test carrier of claim 1, wherein the glass member has a tetragonal shape, and
wherein a width of the glass member is in a range of about 1 cm to about 15 cm.

6. The semiconductor test carrier of claim 1, wherein the glass member comprises a sapphire glass.

7. A semiconductor test apparatus, comprising:
a lower housing that provides a test space;
a window plate in the test space; and
a hot electron analysis (HEA) lens downwardly spaced apart from the window plate,
wherein the window plate comprises:
a plate body; and
a support device coupled to the plate body,
wherein the plate body provides a plate through hole that vertically penetrates the plate body,
wherein at least a portion of the support device is inserted into the plate through hole, and
wherein the support device provides a placement hole that is downwardly recessed from a top surface of the support device.

8. The semiconductor test apparatus of claim 7, wherein a bottom surface of the support device is exposed toward the HEA lens.

9. The semiconductor test apparatus of claim 7, wherein the placement hole has a tetragonal shape, and
wherein a width of the placement hole is in a range of about 0.5 cm to about 5 cm.

10. The semiconductor test apparatus of claim 7, wherein the support device includes a sapphire glass.

11. The semiconductor test apparatus of claim 7, further comprising an insertion member in the plate through hole, the insertion member supporting the support device.

12. The semiconductor test apparatus of claim 7, wherein the window plate further includes a lower support member coupled to a bottom surface of the plate body, the lower support member being disposed below the plate through hole, and
wherein the support device is supported by a top surface of the lower support member.

13. The semiconductor test apparatus of claim 7, further comprising:
a probe card on the window plate; and
a tester configured to supply the probe card with a test power.

14. A semiconductor test method, comprising:
placing a single semiconductor chip having a tetragonal shape on a semiconductor test apparatus;
applying, by using a probe card of the semiconductor test apparatus, a test power to the single semiconductor chip; and
measuring, by using a hot electron analysis (HEA) lens, a characteristic of the single semiconductor chip.

15. The semiconductor test method of claim 14, wherein the placing the single semiconductor chip comprises:
placing the single semiconductor chip having the tetragonal shape in a test space provided by a lower housing of the semiconductor test apparatus, the semiconductor test apparatus further comprising a window plate in the test space, and a semiconductor test carrier on the window plate, and
wherein the placing the single semiconductor chip in the test space comprises placing the single semiconductor chip on a support plate of the semiconductor test carrier, the support plate comprising: a support body having a disk shape; and a glass member coupled to the support body, wherein the support body provides a placement hole that vertically penetrates the support body, and at least a portion of the glass member is inserted into the placement hole.

16. The semiconductor test method of claim 15, wherein the placing the single semiconductor chip on the support plate comprises placing the single semiconductor chip on the glass member.

17. The semiconductor test method of claim 16, wherein the measuring comprises measuring, by using the HEA lens, the characteristic from a bottom surface of the single semiconductor chip through the window plate and the glass member, the HEA lens being downwardly spaced apart from the window plate.

18. The semiconductor test method of claim 14, wherein the placing the single semiconductor chip comprises placing the single semiconductor chip in a test space provided by the semiconductor test apparatus, wherein the semiconductor test apparatus comprises a lower housing that provides the test space and a window plate in the test space, and
wherein the placing the sing semiconductor chip in the test space comprises placing the single semiconductor chip on the window plate.

19. The semiconductor test method of claim 18, wherein the window plate comprises: a plate body, and a support device coupled to the plate body, wherein the support device provides a placement hole downwardly recessed from a top surface of the support device, and
wherein the placing the single semiconductor chip on the semiconductor test apparatus comprises placing the single semiconductor chip in the placement hole.

20. The semiconductor test method of claim 14, wherein the applying the test power comprises applying the test power to the single semiconductor chip by allowing a needle of the probe card to contact a top surface of the single semiconductor chip.
